(19) United States
(12) Patent Application Publication
(10) Pub. No.: US 2006/0088088 A1
(43) Pub. Date: Apr. 27, 2006

(54) LOOK-AHEAD EQUALIZER AND METHOD FOR DETERMINING OUTPUT OF LOOK-AHEAD EQUALIZER

(76) Inventors: Tsu-Chun Liu, Hsinchu (TW); Ming-Lu Wu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/906,537

(22) Filed: Feb. 24, 2005

(30) Foreign Application Priority Data
Oct. 27, 2004 (TW) 93132507

(51) Int. Cl. H03H 7/30

(52) U.S. Cl. 375/232

(57) ABSTRACT

A look-ahead equalizer is provided. The equalizer has an equalizer without a first tap, a look-ahead unit, and a slicer unit. The equalizer without a first tap outputs a pre-filter output and a state reference signal. The look-ahead unit is coupled to the output of the equalizer without a first tap for generating a first, a second, and a third equalizer look-ahead values according to the state reference signal. The slicer unit is coupled to the look-ahead unit. The slicer unit comprises plural state slicer units. Each state slicer unit receives the first, the second, and the third equalizer look-ahead values, and then selects one of them according to a comparison result of the state slicer unit and the state reference signal.

### CROSS-REFERENCE TO RELATED APPLICATION

This application claims the priority benefit of Taiwan application serial no. 93132507, filed on Oct. 27, 2004.

### BACKGROUND OF THE INVENTION

1. Field of the Invention

The present invention relates to an equalizer, and more particularly, to an equalizer adapted for a Gigabit Ethernet.

2. Description of the Related Art

A Gigabit Ethernet card generally comprises analog front ends (AFEs), equalizers and slicers. Signals received by receivers are usually interrupted by intersymbolinterference (ISI), crosstalk, echoes, or other noises. The receivers must equalize all channels to compensate ISI loss and harmonic distortions. Decision Feedback Equalizers (DFEs) are devices often used to remove harmonic distortions. Generally, a DFE method uses a nonlinear equalizer to equalize channels, which is based on useing feedback loops of pre-determined symbols.

In the high-speed application field, such as the Gigabit Ethernet, the symbol rate is tremendously fast. Equalization and decoded computation by the DFE must be completed in an 8-ns pulse period. In such a short period of time, the issue with respect to critical paths will occur. In other words, if the transmitting length between two neighboring flip-flops is larger than the equivalent length of 8 ns, the DFE will not operate functionally.

The output of the DFE can generally be described as
DFEOUTPUT=C1×D1+C2×D2+C3×D3+C4×D4 . . .

Wherein, C1 and D1 are, respectively, the factors and the outputs of different levels, such as flip-flops. C1×D1 is called the first tap. FIG. 1 illustrates a configuration showing an equalizer without a first tap. A first tap 1 2 of the equalizer is moved to the outside of an equalizer 10. FIG. 2 is a configuration showing a five-level pre-filter equalizer. The first tap of the filter is separated from the equalizer. The output of the DFE 10 is the pre-filter output. The output does not include the first tap 12, i.e., C1×D1. The pre-filter output and the first tap 12, i.e., C1×D1, constitute an equalizer output EQout. The equalizer output EQout is transmitted to a slicer 20.

In order to enhance the processing speed of the DFE, a look-ahead architecture is proposed. The look-ahead technology calculates symbol values for every possible approach in advance. After the correct value is determined, the flip-flop then selects the proper symbol.

FIGS. 3A and 3B are drawings showing look-ahead equalizers without a first tap corresponding with different types of slicers. Wherein, the slicer in FIG. 3A is called a Y-type slicer. The slicer in FIG. 3B is called an X-type slicer. As shown in FIG. 3A, the output of the Y-type slicer is 1, 0, and −1. These output values multiply with the first tap factor C1 as first tap look-ahead values. These three look-ahead values 1×C1, 0×C1 and −1×C1 are inputted to a multiplexer 30. When a slicer 22 decides the output value, the output value is transmitted to the equalizer 10 and the multiplexer 30 through a flip-flop D1_sn. According to the output result from the flip-flop D1_sn, the multiplexer 30 selects and transmits one of the look-ahead values 1×C1, 0×C1 and −1×C1 to the slicer 22. In addition, as shown in FIG. 3B, the output of the X-type slicer is 0.5 and −0.5. These output values multiply with the first tap factor Cl as first tap look-ahead values. These two look-ahead values 0.5×C1 and −0.5×C1 are inputted to the multiplexer 32. When a slicer 24 decides the output value, the output value is transmitted to the equalizer 10 and a multiplexer 32 through the flip-flop D1_sn. According to the output result from the flip-flop D1_sn, the multiplexer 30 selects and transmits one of the look-ahead values 0.5×C1 and −0.5×C1 to the slicer 24. In the real architecture, the circuits in FIGS. 3A and 3B are required to prepare four different states.

Though the equalization of the look-ahead DFE can speed up the operation of the DFE, the look-ahead DFE which reduces the area and critical paths is essential to the development of the high speed Gigabit Ethernet.

Moreover, the architecture described above is related to an architecture comprising a five-level slicer. The architecture cannot be directly applied to a more complicated state slicer. Therefore, a look-ahead DFE structure which can be applied to a state slicer is provided herein.

### SUMMARY OF THE INVENTION

Accordingly, the present invention is directed to a look-ahead equalizer and a method for determining an equalizer output to reduce area and critical paths.

The present invention is also directed to a look-ahead equalizer and a method for determining an equalizer output. The equalizer and the method can be applied to a more complicated system with state slicers.

In order to achieve the objects described above, the present invention provides a look-ahead equalizer, which comprises an equalizer without a first tap, a look-ahead unit and a slicer unit. The equalizer without a first tap serves to output a pre-filter output signal and a state reference signal. The state reference signal can be, for example, a five-level slicer output. The look-ahead unit is coupled to an output of the equalizer without the first tap and generates a first, a second, and a third equalizer look-ahead output values according to the state reference signal. The slicer unit is coupled to the look-ahead unit. The slicer unit further comprises a plurality of state slicer units. Each of the state slicer units receives the first, the second, and the third equalizer look-ahead output values, compares a state slicer output value from the slicer unit with the state reference signal, and selects one of the first, the second and the third equalizer look-ahead output values.

According to an embodiment of the present invention, each of the state slicer units comprises: a selector, a state slicer, and a comparator. The selector receives the first, the second, and the third equalizer look-ahead output values. The state slicer is coupled to the selector, receives one of the first, the second, and the third equalizer look-ahead output values, and outputs a state slicer output value. The comparator is coupled to the state slicer and the selector, serves to compare the state slicer output value with the state reference signal, and, according to a comparison result, selects one of the first, the second, and the third equalizer look-ahead output value.

According to an embodiment of the present invention, the look-ahead unit separately adds the state reference signal with a preset value, then multiplies with a first tap factor, and adds with the pre-filter output signal, so as to generate the first, the second, and the third equalizer look-ahead output values. The preset value mentioned above is 0.5, 0 and −0.5.

According to an embodiment of the present invention, the first, the second, and the third equalizer look-ahead output values descend. When the state slicer output value is larger than the state reference signal, the selector outputs the first equalizer look-ahead output value. When the state slicer output value is equal to the state reference signal, the selector outputs the second equalizer look-ahead output value. When the state slicer output value is smaller than the state reference signal, the selector outputs the third equalizer look-ahead output value.

In addition, the present invention further provides a method for determining an equalizer output. The method determines the equalizer output according to a slicer output value from a slicer unit, wherein the slicer unit is coupled to an output of the equalizer. The method comprises generating a pre-filter output signal with a state reference signal; a first, a second, and a third equalizer look-ahead values are generated according to the state reference signal; the slicer output value and the state reference signal are compared to generate a comparison result, and outputting one of the first, the second, and the third equalizer look-ahead output values according to the comparison result.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a configuration showing an equalizer without a first tap.

FIG. 2 is a configuration showing a five-level pre-filter equalizer.

FIGS. 3A and 3B are drawings showing look-ahead equalizers without a first tap; wherein FIG. 3A is directed to a Y-type slicer and FIG. 3B to an X-type slicer.

FIG. 4 is a schematic drawing showing a state slicer.

FIG. 5 is a schematic configuration showing a look-ahead equalizer according to an embodiment of the present invention.

### DESCRIPTION OF SOME EMBODIMENTS

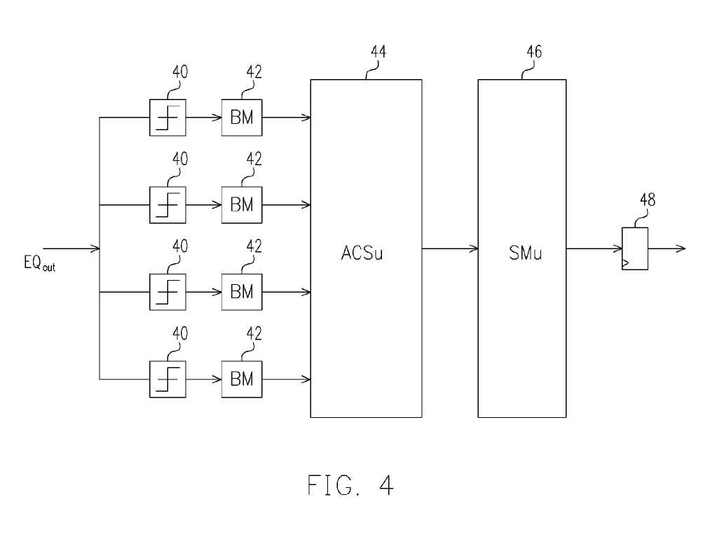

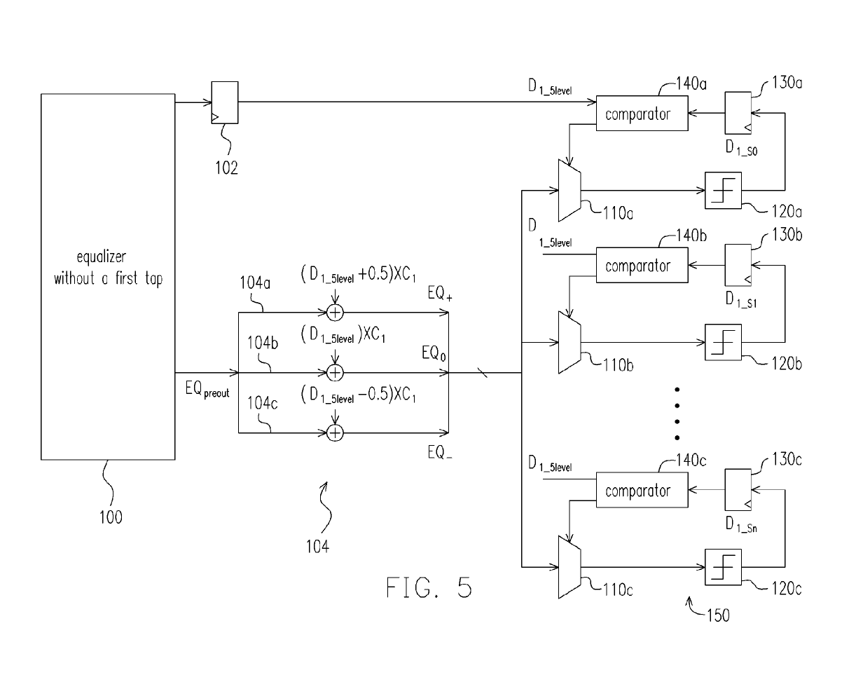

FIG. 4 is a schematic drawing showing a state slicer. FIG. 5 is a schematic configuration showing a look-ahead equalizer according to an embodiment of the present invention. The look-ahead equalizer can be applied to state slicer architecture.

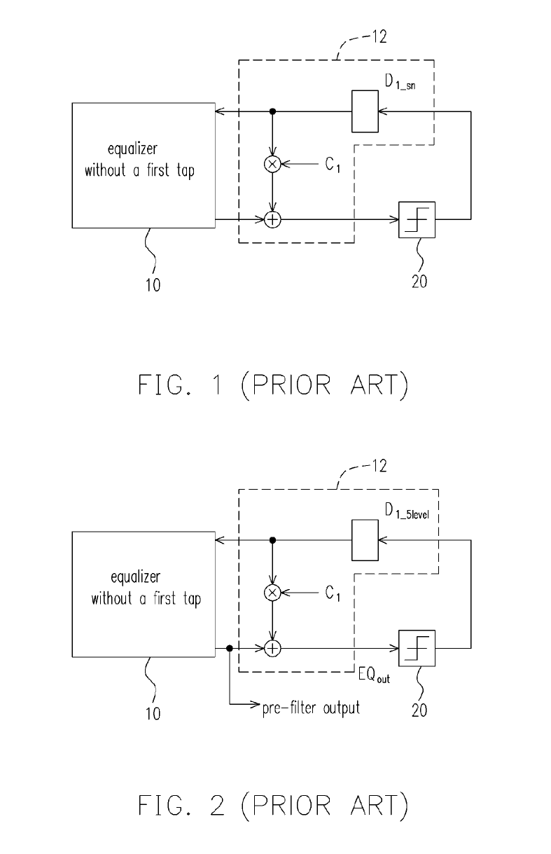

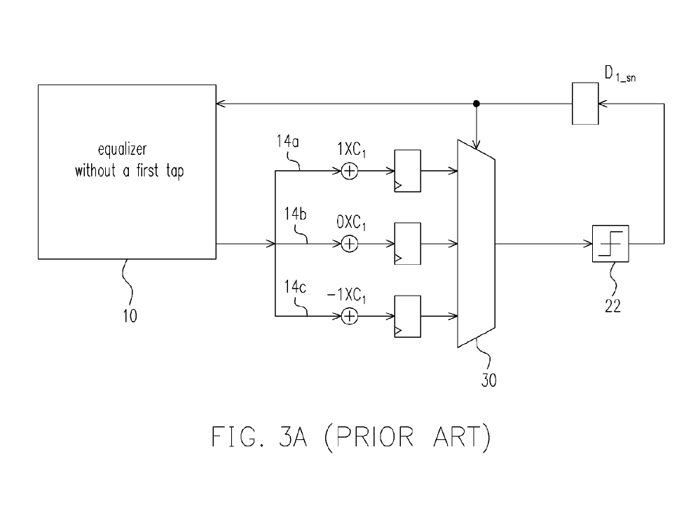

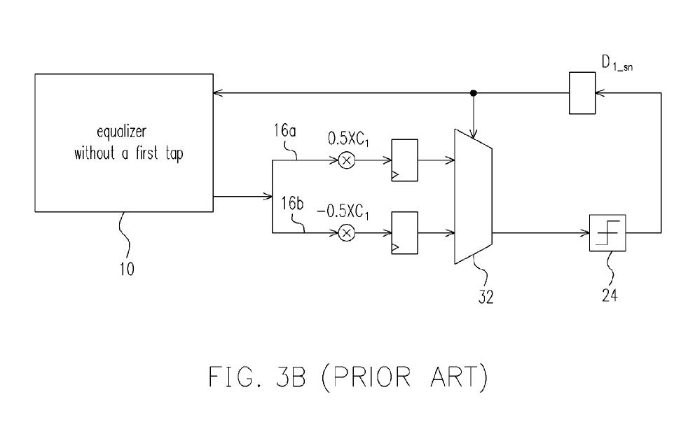

The architecture of the state slicer is more complicated than those of five-level slicers described in FIGS. 1-3. The five-level slicer, after receiving the equalizer output EQout, outputs five values, i.e., 1, 0.5, 0, −0.5, and −1. As shown in FIG. 4, the state slicer separately outputs the equalizer output EQout to a plurality of slicers 40. Each output of the slicers 40 is inputted to one of branch metrics 42. Each of the branch metrics 42 compares the input with output from the corresponding slicer 40 for compensation. All of the outputs of the branch metrics 42 are inputted into an add-compare-select unit (ACSu) 44 for adding and comparing each slicer status, and selecting a suitable value. A survivor memory unit (SMu) 46 will store the survivor state and output the survivor state to a flip-flop.

FIG. 5 shows a look-ahead equalizer which can be a Decision Feedback Equalizer (DFE). The look-ahead equalizer comprises an equalizer without a first tap 100, a look-ahead unit 104 and a slicer unit 150. The equalizer without a first tap 100 serves to output a pre-filter output signal EQpreout and a state reference signal. The state reference signal can be, for example, an output D1_{—}5level of a five-level slicer. The look-ahead unit 104 is coupled to the equalizer without a first tap 100, and outputs a first, a second and a third equalizer look-ahead output values EQ+, EQ0 and EQ− according to the state reference signal. The slicer unit 150 is coupled to the look-ahead unit 104. The slicer unit 150 further comprises plural state slicer units. Each of the state slicer units receives the first, the second and the third equalizer look-ahead output values EQ+, EQ0 and EQ−. Each of the state slicer unit compares a state slicer output value of each of the state slicer unit with the state reference signal so as to select one of the first, the second and the third equalizer look-ahead output values EQ+, EQ0 and EQ−.

Referring to FIG. 5, the DFE without a first tap (hereinafter “DFE”) 100 outputs the pre-filter output EQpreout, and the pre-filter output EQpreout is inputted to the look-ahead unit 104. The look-ahead unit 104 outputs the equalizer output values EQ+, EQ0 and EQ−. The equalizer look-ahead output values EQ+, EQ0 and EQ− are shown in the following formulas (1)-(3), wherein EQpreout=C2×D2+C3×D3+ . . . . In the equalizer 100, the length of the pre-filter output EQpreout is equal to that of the equalizer output EQout without a first tap.
EQ+=C1×(D1_{—}5level+0.5)+C2×D2+C3×D3+ (1)
EQ0=C1×(D1_{—}5level)+C2×D2+C3×D3+ (2)
EQ−=C1×(D1_{—}5level−0.5)+C2×D2+C3×D3+ (3)

It means that the pre-filter output EQpreout passes through the paths 104a, 104b and 104c of the look-ahead unit 104, respectively, and is added with the multiplication of the first tap factor C1 of the DFE 100 and D1_{—}5level+0.5, D1_{—}5level, and D1_{—}5level−0.5, respectively, to serve as the look-ahead values. Wherein, D1_{—}5level can be a state reference signal, such as the first tap state output of the five levels of a flip-flop 102. According to the five levels of 1, 0.5, 0, −0.5, and −1, differences between the five levels and D1_{—}5level are 0.5 or −0.5. In the look-ahead unit 104, the D1_{—}5level and the biased value of the D1_{—}5level±0.5 serve as the look-ahead values. In the example of the equalizer output EQ=0.6, the 5-level slicer output D1_{—}5level is 0.5. According to the standard output of the five levels, 1, 0.5, 0, −0.5, and −1, the corresponding output of the equalizer output EQ=0.6 may be 1, 0.5, and 0, i.e., 0.5 and 0.5±0.5.

The equalizer output values EQ+, EQ0 and EQ− are then transmitted to the plural decision units. Each of the decision units comprises multiplexers 110a/110b/ . . . /110c, state slicers 120a/120b/ . . . /120c, flip-flops 130a/130b/ . . . /130c, and comparators 140a/140b/ . . . /140c.

In the example of the first state slicer 120a, the flip-flop 130a receives the state D1_s0 from the state slicer output. The state D1_s0 is then inputted to the comparator 140a. The state D1_s0 is the first tap state output value of the actual operation of the circuit. The comparator 140a receives and compares the state D1_s0 outputted from the flip-flop 130a with the state D1_{—}5level from the flip-flop 102. The comparison result is then transmitted to the multiplexer 110a for selection.

The comparator 140a compares the real output state D1_s0 with the five-level output D1_{—}5level to select the correct look-ahead value. The comparator 140a will generate three comparison results—larger, equal and smaller. When the real output state D1_s0 is larger than the five-level output D1_{—}5level, which represents D1_s0>D1_{—}5level and the look-ahead value D1_{—}5level+0.5 is selected. When the real output state D1_s0 is equal to the five-level output D1_{—}5level, which represents D1_s0 =D1_{—}5level and the look-ahead value D1_{—}5level is selected. When the real output state D1_s0 is smaller than the five-level output D1_{—}5level, which represents D1_s0<D1_{—}5level and the look-ahead value D1_{—}5level−0.5 is selected. According to the comparison result from the comparator 140a, the multiplexer 110a selects one of the equalizer output values EQ+, EQ0 and EQ−.

According to the look-ahead equalizer and the method for determining the equalizer output of the present invention, the area and the critical paths can be reduced. In addition, the present invention can also be applied to a system which contains more complicated state slicers.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A look-ahead equalizer, comprising:
an equalizer without a first tap, serving to output a pre-filter output signal and a state reference signal;
a look-ahead unit, coupled to an output of the equalizer without the first tap, generating a first, a second, and a third equalizer look-ahead output values according to the state reference signal; and
a slicer unit, coupled to the look-ahead unit, the slicer unit further comprising a plurality of state slicer units, wherein each of the state slicer units receives the first, the second, and the third equalizer look-ahead output values, compares a state slicer output value from the state slicer unit with the state reference signal, and selects one of the first, the second, and the third equalizer look-ahead output values.

2. The look-ahead equalizer of claim 1, wherein each of the state slicer units comprises:
a selector, receiving the first, the second, and the third equalizer look-ahead output values;
a state slicer, coupled to the selector, receiving one of the first, the second, and the third equalizer look-ahead output values, and outputting the state slicer output value; and
a comparator, coupled to the state slicer and the selector, serving to compare the state slicer output value with the state reference signal, and, according to the comparison result, making the selector select one of the first, the second, and the third equalizer look-ahead output values.

3. The look-ahead equalizer of claim 1, wherein the look-ahead unit separately adds the state reference signal with a preset value, then multiplies the addition result with a first tap factor, adds the multiplication result with the pre-filter output signal, to generate the first, the second, and the third equalizer look-ahead output values.

4. The look-ahead equalizer of claim 3, wherein the preset value is 0.5, 0 and −0.5, respectively.

5. The look-ahead equalizer of claim 4, wherein the first, the second, and the third equalizer look-ahead output values are descending; when the state slicer output value is larger than the state reference signal, the selector outputs the first equalizer look-ahead output value; when the state slicer output value is equal to the state reference signal, the selector outputs the second equalizer look-ahead output value; and when the state slicer output value is smaller than the state reference signal, the selector outputs the third equalizer look-ahead output value.

6. The look-ahead equalizer of claim 1, wherein the state reference signal is a five-level slicing state signal.

7. A method for determining an equalizer output, the method determining an equalizer output according to a slicer output value from a slicer unit, wherein the slicer unit is coupled to the output of the equalizer, the method for determining the equalizer output comprising:
generating a pre-filter output signal and a state reference signal;
generating a first, a second, and a third equalizer look-ahead output values according to the state reference signal; and
comparing the slicer output value with the state reference signal to generate a comparison result, and outputting one of the first, the second, and the third equalizer look-ahead output values according to the comparison result.

8. The method for determining an equalizer output of claim 7, wherein the step of generating the first, the second, and the third equalizer look-ahead output values further comprises separately adding the state reference signal with a preset value, then multiplying the addition result with a first tap factor, and adding the multiplication result with the pre-filter output signal.

9. The method for determining an equalizer output of claim 8, wherein the preset value is 0.5, 0 and −0.5, respectively.

10. The method for determining an equalizer output of claim 9, wherein the first, the second, and the third equalizer look-ahead output values are descending; when the slicer output value is larger than the state reference signal, the selector outputs the first equalizer look-ahead output value; when the slicer output value is equal to the state reference signal, the selector outputs the second equalizer look-ahead output value; and when the slicer output value is smaller than the state reference signal, the selector outputs the third equalizer look-ahead output value.

11. The method for determining an equalizer output of claim 7, wherein the state reference signal is a five-level slicing state signal.
